(19) United States
(12) Patent Application Publication
(10) Pub. No.: US 2008/0035313 A1
(43) Pub. Date: Feb. 14, 2008

(54) Heat-Conducting Base and Isothermal Plate having the same

(76) Inventor: Hul-Chun Hsu, Taichung City (TW)

Correspondence Address: HDSL, 4331 STEVENS BATTLE LANE, FAIRFAX, VA, 22033, US

(21) Appl. No.: 11/463,438

(22) Filed: Aug. 9, 2006

(51) Int. Cl. H05K 7/20

(52) U.S. Cl. 165/104.33; 361/700

(57) ABSTRACT

A isothermal plate includes a heat-conducting base and a plurality of heat pipe. After the heat-conducting base is combined with the heat pipes, they are subjected to a pressing action. The heat-conducting base has a first plate body provided thereon with a plurality of hollow ribs extending from its one side to another side. The hollow rib is arranged at an interval with each other, so that a hollowed section is formed between any two adjacent hollow ribs. Each hollow rib is provided therein with a deep hole extending along its lengthwise direction, so that the heat pipes are respectively inserted into each deep hole and accommodated therein.

### BACKGROUND OF THE INVENTION

1. Field of the Invention

The present invention relates to a heat-conducting base and an isothermal plate having the heat-conducting base. Especially, the present invention relates to a heat-conducting base for combining with a heat pipe, and an isothermal plate made by pressing so as to allow the heat-conducting base to be more tightly connected to the heat pipe.

2. Description of Prior Art

With regard to the technique for combining the heat pipe and the heat-conducting base, for example, it is disclosed in Taiwan Patent Publication No.200421071 entitled “Method for combining heat pipes with a heat-conducting base”.

However, the technique disclosed in the above-mentioned patent document lies in that holes are provided on a solid heat-conducting base to correspond to the heat pipes. Further, after the heat pipes are embedded into the holes, an external force is applied to the heat-conducting base so that it is deformed together with the heat pipes. In this way, the heat pipes can be tightly combined into the holes of the heat-conducting base.

It is well known that when a metal is pressed to generate the plastic deformation due to the external force, it is necessary to utilize a stress, so that the material can generate a plastic flow to cause a permanent deformation. However, in the above-mentioned patent document, a solid heat-conducting base is directly pressed. Theoretically, the applied external force should be very large. Therefore, it may be more or less difficult in practical production. At the same time, since the above-mentioned patent document does not provide a guiding means for the plastic deformation, a plastic flowing pattern will be formed on the pressing surface, resulting in the unevenness of the surface. Also, the compression and deformation of the heat pipe will be unstable. The width of the heat-conducting base also becomes larger, and the outer edge of the width is also uneven. Under these circumstances, the amount of deformation of each heat pipe is not uniform, so that it is hard to control the quality of the finished products.

In view of the above, the inventor proposes the present invention to overcome the above problems based on his expert experiences and deliberate researches.

### SUMMARY OF THE INVENTION

The present invention is to provide a heat-conducting base and an isothermal plate having the heat-conducting base to solve the above drawbacks. In this way, after the heat-conducting base is combined with the heat pipe, it is more suitable to make the heat-conducting base to be more tightly combined with the heat pipe by pressing.

The present invention provides a heat-conducting base having a first plate body. On the first plate body, a plurality of hollow ribs is provided to extend from a side thereof to another side. Those hollow ribs are arranged at intervals, so that a hollowed section is formed between any two adjacent hollowed ribs. Each hollowed rib has a deep hole therein extending along its lengthwise direction, so that a plurality of heat pipes are respectively inserted into each deep hole and accommodated therein.

The present invention provides an isothermal plate made by pressing after the above-mentioned heat-conducting base and heat pipes are combined with each other. Each hollow rib and heat pipe are flattened after pressing. Further, each heat pipe is brought into a tight and planar contact with the wall of its corresponding deep hole in the pressing direction (i.e., at the thus-formed flattened place after pressing), so that each heat pipe can be combined with the heat-conducting base.

### BRIEF DESCRIPTION OF THE DRAWINGS

FIG. 1 is an exploded perspective view showing the heat-conducting base and the heat pipe of the present invention;

FIG. 2 is a schematic view showing the action of pressing after the heat-conducting base and the heat pipe of the present invention are combined with each other;

FIG. 3 is a cross-sectional view of FIG. 2 after pressing;

FIG. 4 is a partially enlarged view of FIG. 3;

FIG. 5 is a perspective view of the isothermal plate of the present invention;

FIG. 6 is a schematic view showing the action of pressing applied to another embodiment of the present invention;

FIG. 7 is a cross-sectional view of FIG. 6 after pressing; and

FIG. 8 is a cross-sectional view of still another embodiment of the present invention.

### DETAILED DESCRIPTION OF THE INVENTION

In order to make the Examiner better understand the characteristics and the technical contents of the present invention, a detailed description relating to this will be made with reference to the accompanying drawings. However, it should be understood that the drawings are illustrative but not used to limit the scope of the present invention.

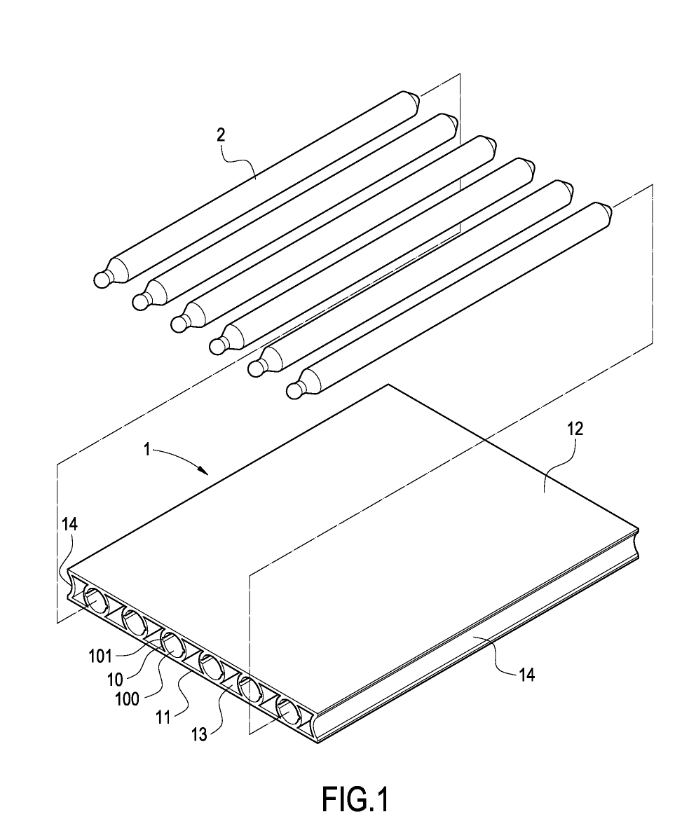

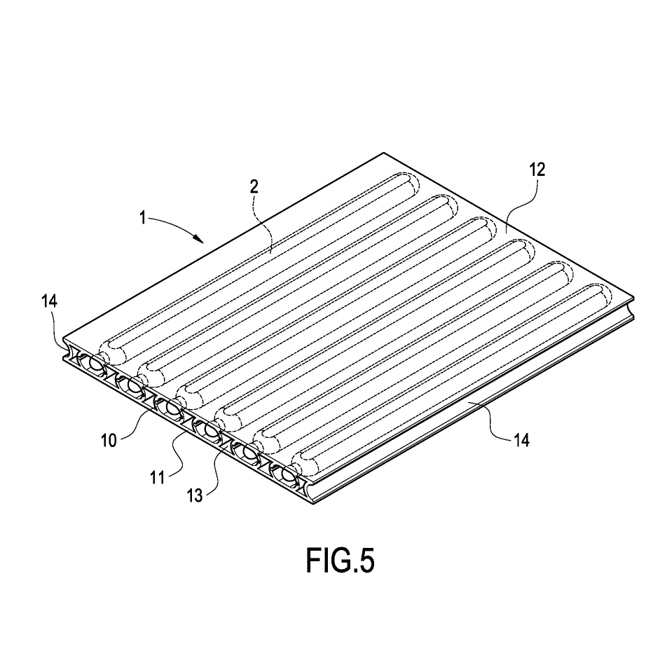

With reference to FIG. 1 and FIG. 5, they are an exploded perspective view of the heat-conducting base and heat pipe and the perspective view of the isothermal plate of the present invention, respectively. The present invention provides a heat-conducting base and an isothermal plate having the heat-conducting base. The isothermal plate 3 comprises the heat-conducting base 1 and a plurality of heat pipes 2. After the heat-conducting base and the heat pipes are combined with each other, they are pressed to form the isothermal plate. The heat-conducting base 1 can be integrally formed by extrusion, such as aluminum extrusion. The heat-conducting base 1 has a first plate body 11 and a second plate body 12. The first plate body 11 and the second plate body 12 are parallel with each other and has a space therebetween for providing with a plurality of hollow ribs 10. Further, the first plate body 11, the second plate body 12 and each hollow rib 10 are integrally formed.

Each hollow rib 10 is formed into an elongated shape and extends from one side of the first and second plate body 11, 12 to another side. Each hollow rib 10 is arranged at an interval and parallel to each other, so that a hollowed section 13 can be formed between any two adjacent hollow ribs 10. Further, each hollow rib 10 has a deep hole 100 therein along its lengthwise direction, so that each heat pipe 2 can be inserted into each deep hole 100 and accommodated therein. On the edge of each deep hole 100 is further provided with at least one fine hole 101. Each fine hole 101 also extends along the lengthwise direction of the hollow rib 10. At the same time, the heat-conducting base 1 is formed with one curved side 14 recessed inwardly on each side of the first and second plate bodies 11, 12. The two sides 14 are also arranged at an interval and parallel to its adjacent hollow rib 10, thereby to enhance the structural strength of both sides of the first and second plate bodies 11, 12.

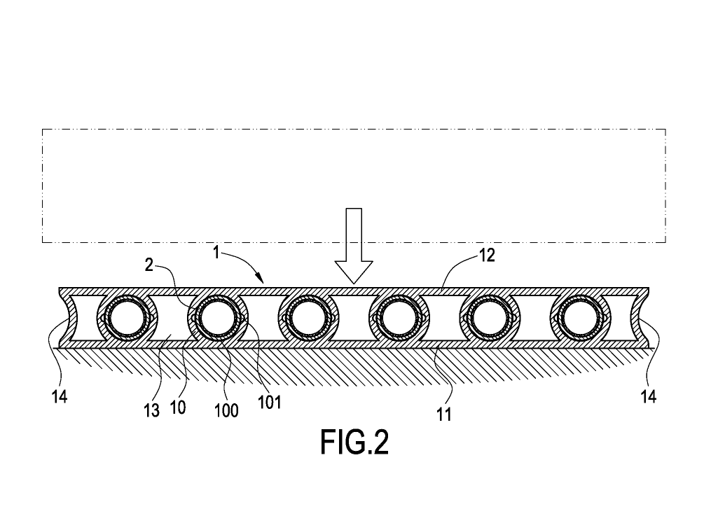

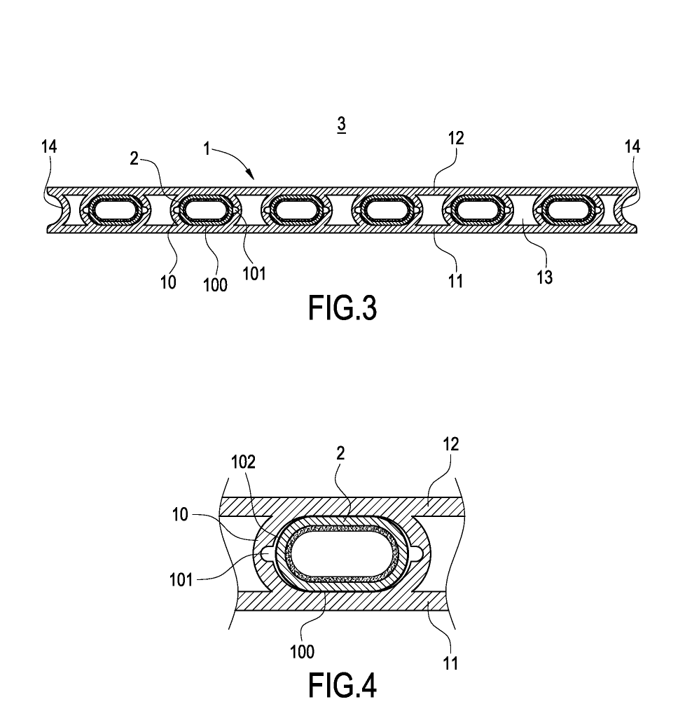

As shown in FIG. 2, after each heat pipe 2 is inserted into each deep hole 100 of the heat-conducting base 1, the first and second plate bodies 11, 12 of the heat-conducting base 1 are subjected to pressing. In pressing, the first plate body 1 is horizontally disposed on a working table. An external force is applied to the second plate body 12, so that each hollow rib 10, heat pipe 2 and the two sides 14 are plastically deformed due to the external force. Each hollowed section 13 is used to provide a direction and space for guiding the plastic flow of the material of each the abovementioned portion, thereby to reduce the resistance generated in applying the external force. In this way, it is convenient to perform the pressing action to the heat-conducting base 1. At the same time, since each hollowed section 13 provides the flowing direction and space to the plastically deformed materials, after each hollow rib 10 and heat pipe 2 are plastically deformed, the degree and the amount of each hollow rib and heat pipe become more uniform, as shown in FIG. 3. Each hollowed section 13 further acts as a heat-dissipating passage for the isothermal plate 3, and helps to reduce the weight of the isothermal plate 3.

With reference to FIG. 4, after the heat-conducting base 1 has been pressed, each hollow rib 10 and heat pipe 2 are flattened, so that each heat pipe 2 is brought into a tight and planar contact with the wall of its corresponding deep hole 100 in the pressing direction (i.e., at the flattened place after pressing). In this way, the heat-conducting base 1 is combined with each heat pipe 2. Further, a gap 102 is slightly formed between the heat pipe 2 and both sides of the deep hole 100. At this time, a heat-conducting medium such as heat-conducting paste or solder can be injected into each fine hole 101, so that the heat-conducting medium can flow into the gap 102 between the heat pipe 2 and the deep hole 100. Then, by passing through a solder furnace, each heat pipe 2 can be further bonded with the heat-conducting base 1 to form one body. In this way, the isothermal plate 3 of the present invention shown in FIG. 5 can be obtained.

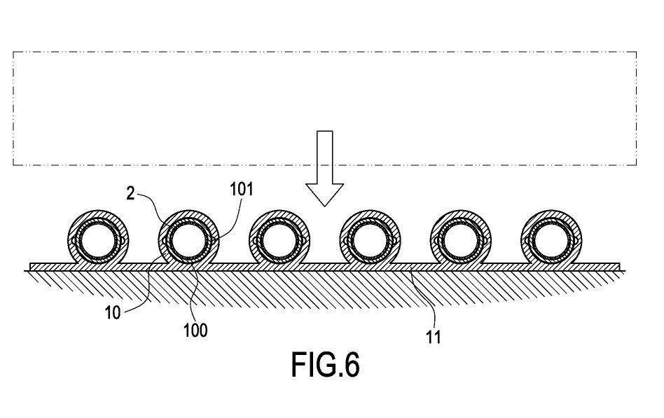

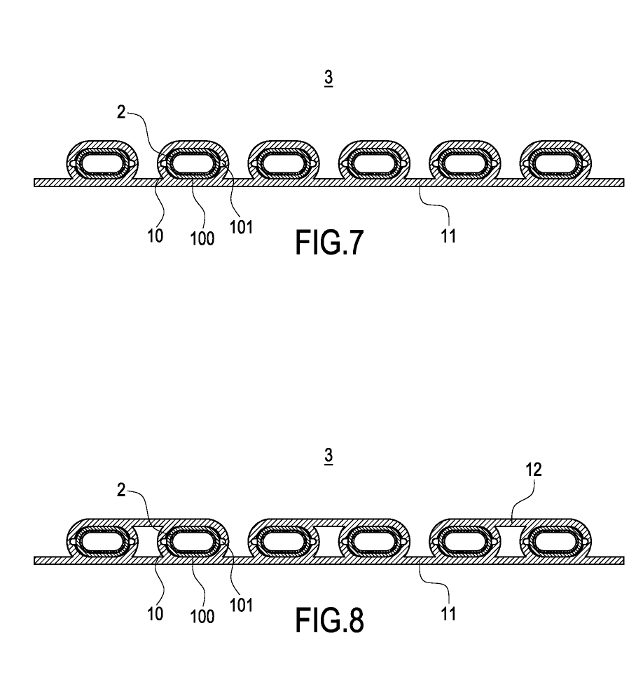

Further, as shown in FIG. 6 and FIG. 7, the second plate body 12 of the above embodiment is not the necessary element of the heat-conducting base 1 or isothermal plate 3 of the present invention. When the second plate body 12 is omitted, since the curved surface of each hollow rib 10 is exposed to the outside, each hollow rib 10 has a larger surface area to contact with the external air, thereby to increase the hear-dissipating area of the heat-conducting base 1 or the isothermal plate 3 without affecting the pressing action. Further, as shown in FIG. 8, the second plate body 12 can be formed into a plurality of strips each provided between any two adjacent hollow ribs 10. Further, each of those second plate bodies 12 is arranged at interval with each other.

Therefore, with the above construction, the heat-conducting base and the isothermal plate having the heat-conducting base can be achieved.

According to the above, the present invention indeed achieves the desired effects and solves the drawbacks of prior art by using the above-mentioned structure. Further, the present invention involves the novelty and inventive steps, and thus conforms to the requirements for an invention patent.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A heat-conducting base adapted to receive a plurality of heat pipes, comprising:
a first plate body provided with a plurality of hollow ribs thereon, each hollow rib extending along a lengthwise direction and arranged with an interval respected to another; and
a hollowed section formed between any two adjacent hollow ribs,
wherein each hollow rib has a deep hole therein extending along the lengthwise direction thereof, so that the heat pipes are respectively inserted into each deep hole and accommodated therein.

2. The heat-conducting base according to claim 1, further comprising a plurality of second plate bodies each formed into a strip, wherein the second plate body is respectively provided above any two adjacent hollow ribs, and the second plate bodies are arranged at the interval with each other.

3. The heat-conducting base according to claim 1, further comprising a second plate body arranged to be parallel to the first plate body, wherein the hollow ribs are provided between the first plate body and the second plate body.

4. The heat-conducting base according to claim 3, wherein both sides of the first and the second plate bodies are respectively provided with a curved side recessed inwardly, and each side is arranged to be parallel to adjacent hollow rib thereof.

5. The heat-conducting base according to claim 1, wherein the heat-conducting base is formed by extrusion.

6. The heat-conducting base according to claim 1, wherein an edge of each deep hole is further provided with a fine hole extending along the lengthwise direction of corresponding hollow rib.

7. An isothermal plate, comprising:
a heat-conducting base having a first plate body, the first plate body provided thereon with a plurality of hollow ribs extending from one side to another side thereof, the hollow ribs arranged at an interval with each other, and each hollow rib provided therein with a deep hole extending along a lengthwise direction thereof; and
a plurality of heat pipes each inserted into the deep hole of the hollow rib and accommodated therein;
wherein each hollow rib and heat pipe are flattened, and each heat pipe is brought into a tight and planar contact with wall of corresponding deep hole at the flattened place, so that each heat pipe is combined with the heat-conducting base.

8. The isothermal plate according to claim 7, wherein the heat-conducting base is further provided with a plurality of second plate bodies each formed into a strip, the second plate bodies are respectively provided above any two adjacent hollow ribs, and the second plate bodies are arranged at the interval with each other.

9. The isothermal plate according to claim 7, wherein the heat-conducting base further has a second plate body arranged to be parallel to the first plate body, and the hollow ribs are provided between the first plate body and the second plate body.

10. The isothermal plate according to claim 9, wherein both sides of the first and the second plate bodies are respectively formed with a curved side recessed inwardly, and each side is arranged to be parallel to adjacent hollow rib thereof.

11. The isothermal plate according to any one of claims 7, wherein the heat-conducting base is formed by extrusion.

12. The isothermal plate according to claim 7, wherein an edge of each deep hole of the heat-conducting base is further provided with a fine hole extending along the lengthwise direction of corresponding hollow rib.
